(19) United States
(12) Patent Application Publication
(10) Pub. No.: US 2012/0249893 A1
(43) Pub. Date: Oct. 4, 2012

(54) TELEVISION APPARATUS AND ELECTRONIC APPARATUS

(76) Inventors: Kiyomi Muro, Hachioji-shi (JP); Nobuhiro Yamamoto, Fussa-shi (JP)

(21) Appl. No.: 13/300,345

(22) Filed: Nov. 18, 2011

(30) Foreign Application Priority Data
Mar. 30, 2011 (JP) 2011-076423

(51) Int. Cl. H04N 5/64; H05K 5/00

(52) U.S. Cl. 348/836; 361/752; 348/E05.128

(57) ABSTRACT

According to one exemplary embodiment, a television apparatus includes: a housing; a circuit board housed in the housing; and an electronic component including a first face placed to a side of the circuit board and a second face placed opposite to the first face, and incorporating a silicon member. The electronic component comprises: an electrode provided at the first face and configured to be electrically connected to the circuit board; and a protrusion provided at the first face, placed between the silicon member and the circuit board, and separated from a surface of the circuit board.

### CROSS REFERENCE TO RELATED APPLICATION(S)

The application is based upon and claims the benefit of priority from Japanese Patent Application No. 2011-076423 filed on Mar. 30, 2011; the entire content of which are incorporated herein by reference.

### FIELD

Exemplary embodiments described herein relate generally to a television apparatus and an electronic apparatus.

### BACKGROUND

Hitherto, there has been known an electronic apparatus that has an electronic component structure such as a semiconductor package, and a board on which the electronic component structure is mounted, and that is configured so that an electrode portion of the electronic component structure is soldered with a solder portion thereof to the board.

### BRIEF DESCRIPTION OF THE DRAWINGS

Exemplary embodiments of the present invention will be described in detail based on the following figures, wherein:

FIG. 1 is a front view showing a television apparatus serving as an electronic apparatus according to a first embodiment;

FIG. 2 is a longitudinally cross-sectional view showing a mounting state of a semiconductor package serving as an electronic component structure according to the first embodiment;

FIG. 3 is a view schematically showing a mounting-process of mounting the semiconductor package according to the first embodiment on a board;

FIG. 4 is a view schematically showing a configuration of a first modification of a semiconductor package according to a second embodiment;

FIG. 5 is a view schematically showing a configuration of a second modification of the semiconductor package according to the second embodiment;

FIG. 6 is a view schematically showing a configuration of a first modification of a semiconductor package according to a third embodiment;

FIG. 7 is a view schematically showing a configuration of a second modification of the semiconductor package according to the third embodiment;

FIG. 8 is a view schematically showing the configuration of the second modification of the semiconductor package according to the third embodiment, which is taken from an angle differing from that at which the view shown in FIG. 7 is taken;

FIG. 9 is a view schematically showing a configuration of a third modification of the semiconductor package according to the third embodiment;

FIG. 10 is a view schematically showing a configuration of a semiconductor package according to a fourth embodiment;

FIG. 11 is a view schematically showing a configuration of a semiconductor package according to a fifth embodiment;

FIG. 12 is a perspective view showing a personal computer serving as an electronic apparatus according to a sixth embodiment; and

FIG. 13 is a perspective view showing a magnetic disc apparatus serving as an electronic apparatus according to a seventh embodiment.

### DETAILED DESCRIPTION OF THE EXEMPLARY EMBODIMENTS

In general, according to one exemplary embodiment, a television apparatus includes: a housing; a circuit board housed in the housing; and an electronic component including a first face placed to a side of the circuit board and a second face placed opposite to the first face, and incorporating a silicon member, wherein the electronic component comprises: an electrode provided at the first face and configured to be electrically connected to the circuit board; and a protrusion provided at the first face, placed between the silicon member and the circuit board, and separated from a surface of the circuit board.

Hereinafter, embodiments are described in detail with reference to the accompanying-drawings. Incidentally, the following plurality of embodiments includes similar components. Therefore, in the following description, the similar components are designated with common reference numeral. In addition, the redundant description of the similar components is omitted.

### First Embodiment

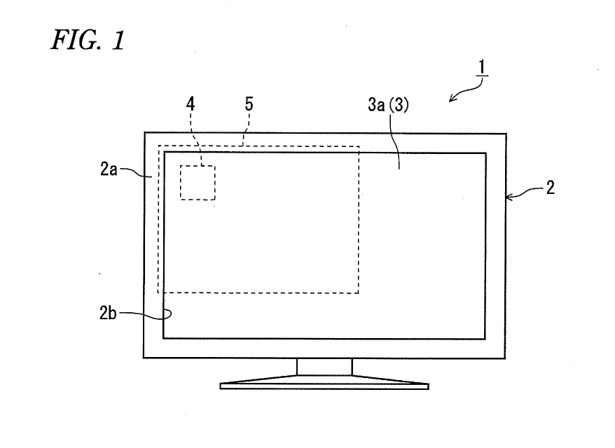

First, a first embodiment is described with reference to FIGS. 1 to 3.

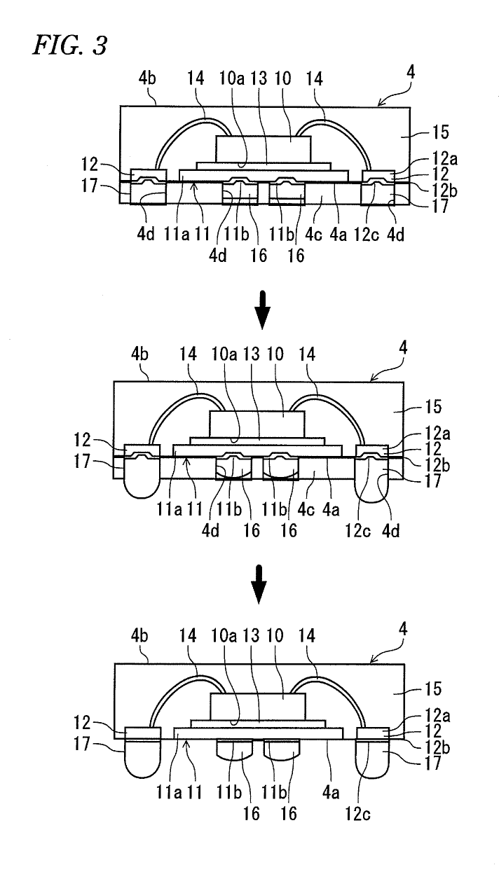

As shown in FIG. 1, a television apparatus 1 serving as an electronic apparatus according to the present embodiment has a rectangle-shaped appearance in front view taken from the front side (display-screen side) thereof (i.e., in view of a front face thereof as projected on a frontal plane) thereof. The television apparatus 1 includes a housing 2, a display panel (e.g., a liquid crystal display (LCD)) 3 serving as a display apparatus (i.e., a display) having a display screen 3a exposed frontward from an opening portion 2b provided in a front face 2a of the housing 2, and a board (a printed circuit board, a circuit board, a printed wiring board, a circuit board, and the like) 5 on which a semiconductor package (a package, heating elements, electronic components, housed components, parts, a ball grid array (BGA), semiconductors, and the like) 4 or the like is mounted. The semiconductor package 4 includes a face (first face) 4a which is directed to the side of the board 5 and connected electrically thereto), and a face (second face) 4b opposite to the face 4a, as shown in FIG. 3. The display panel 3 and the board 5 are fixed to the housing 2 with screws (not shown) or the like.

The display panel 3 is formed like a rectangular flat parallelepiped which is thin in a front-back direction (i.e., a direction perpendicular to a paper plane of FIG. 1). The display panel 3 receives video signals from a video signal processing circuit included in a control circuit (both of which are not shown) configured by a semiconductor package 4 mounted on the board 5. Then, the display panel 3 displays an image such as a still image or a motion picture on a display screen 3a provided on the front face side of the display panel 3. The control circuit includes a tuner, a high-definition multimedia interface (HDMI) signal processing circuit, an audio video (AV) input terminal, a remote control signal receiver, a controller, a selector, on-screen display interface, a storage module (e.g., a read-only memory (ROM), a random access memory (RAM), a hard disk drive (HDD) and the like), and an audio signal processing circuit, or the like (all of which are not shown), in addition to the video signal processing circuit (not shown).

The board 5 is housed at a rear side (i.e., at a side opposite to the display screen 3a) of the display panel 3 in the housing 2. The television apparatus 1 incorporates an amplifier, speakers and the like, which are provided for audio output.

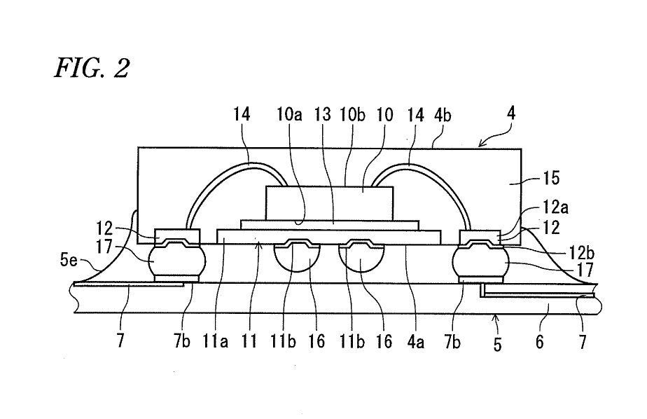

As shown in FIG. 2, the board 5 is configured by materials such as glass-epoxy. The board 5 includes an insulating portion (an insulating layer, a resist layer, a resist portion and the like) 6 and a wiring pattern (a line, a pattern, a non-conductive portion, a conductive portion, a signal line and the like) 7. The wiring pattern 7 is configured by an electrically conductive material such as a copper foil. The wiring pattern 7 is provided with a plurality of electrode pads (a protrusion portion, a plating portion, a non-conductive portion, a conductive portion, and a connection portion, a protrusion and the like) 7b electrically connected to the board 5 and the wiring pattern 7.

The semiconductor package 4 is a surface mount device (SMD). According to the present embodiment, the semiconductor package 4 is configured to be of, e.g., the non-lead type that has no interposer. As shown in FIG. 2, the semiconductor package 4 includes a semiconductor chip (a chip, silicone, a silicon member, a silicon part, a heating element, a component, a semiconductor and the like) 10, a first electrode portion (a part, a protrusion portion, a plating portion, an electrically conductive portion, a connection portion, a protrusion and the like) 11 and a plurality of second electrode portions (a part, a protrusion portion, a plating portion, an electrically conductive portion, a connection portion, a protrusion and the like) 12.

The first electrode portion 11 is connected to a face 10a of the semiconductor chip 10 via an intermediate layer 13. On the other hand, each, of the second electrode portions 12 is connected to the semiconductor package 4 by metallic connection lines 14 connected to the other face 10b provided opposite to the face 10a. The semiconductor package 4 is configured with a resin sealing portion (a resin material, a connection material, a bonding portion, an adhesive member and the like) 15 for sealing the semiconductor package 4, so that the semiconductor package 4, the first electrode portion 11, the second electrode portions 12, the intermediate layer 13 and the connection lines 14 are integral with one another.

The semiconductor package 4 is mounted on the board 5 by bonding the second electrode portions 12 to the electrode pads 7b formed on the board 5 via second solder portions (a resin material, a connection material, a bonding portion, an adhesive member and the like) 17.

The first electrode portion 11 and the second electrode portions 12 have an electrically conductive property. Each of the first electrode portion 11 and the second electrode portions 12 has an associated one of lead frames 11a and 12a connected to the semiconductor chip 10 via the intermediate layer 13, and an associated one of plating layers (a plating portion, under-bump metal, a conductive portion, a heat transfer portion and the like) 11b and 12b each of which is stacked on an associated one of lead frames 11a and 12a. The lead frames 11a and 12a according to the present embodiment are gold-plated layers. The intermediate layer 13 is configured by an adhesive agent or the like with an electrically conductive property.

As shown in FIG. 2, according to the present embodiment, a first solder portion 16 is provided to be separated from the surface of the board 5. The first solder portion 16 is small in amount of solder printed thereon, as compared with the second solder portion 17. That is, the first solder portion 16 is low in height of a part protruded from the face 4a at the side of the board 5 of the semiconductor package 4. Thus, according to the present embodiment, the first solder portion 16 is physically and electrically separated from the board 5 and the wiring patterns 7, as compared with the second solder portion 17. The configuration of the present embodiment may be implemented by reducing the area of a soldering region 11b on which the first solder portion 16 is provided, instead of adjusting an amount of solder printed thereon.

Thus, according to the present embodiment, the first solder portion 16 contributes to the enhanced heat dissipation efficiency in a state in which the first solder portion 16 is not electrically connected to the board 5 and the wiring patterns 7. In addition, because it is unnecessary to provide a plating region or the like, which is used to connect the first solder portion 16 go the board 5, another electronic component or a wiring pattern can be designed to be provided between the first solder portion 16 and the board 5. Thus, the degree of flexibility of design can be enhanced.

The first electrode portion 11 transfers heat of the semiconductor chip 10 serving as a heating element via the first solder portion 16 to the board 5. This heat transfer results in discharge of heat of the semiconductor chip 10 from the board 5. The area of an electrode face lie of the first electrode portion 11 is larger than that of the electrode face 12c of the second electrode 12 serving as another electrode portion. Accordingly, high heat dissipation ability can be assured.

With such a configuration, according to the present embodiment, heat generated by the semiconductor package 4 can efficiently be transferred to the board 5. In addition, the area of a face for dissipation of heat from the semiconductor chip 10 can be assured to be wide. Consequently, the enhancement of the heat dissipation efficiency can be implemented.

Next, a mounting-process of mounting the semiconductor package 4 of the above configuration on the board 5 is described hereinafter.

As shown in FIG. 3, in the mounting-process, e.g., the first solder portion 16 and the second solder portion 17, which configure solder balls, are bonded to the first electrode portion 11 and the second electrode portion 12, respectively. FIG. 3 shows a method for filling, with solder paste, an opening portion 4d of a film 4c provided on the face 4a located on the side of the board 5 of the semiconductor package 4.

Next, the first solder portion 16 and the second solder portion 17 are sandwiched by the board 5 and the semiconductor package 4. Then, the first solder portion 16 and the second solder portion 17 are heated in a reflow process. Accordingly, the first solder portion 16 and the second solder portion 17 are molten to be shaped like a ball. At that time, the film 4c provided on the face 4a is removed. The semiconductor package 4 is placed on the board 5. Since the plating layer 11b is, e.g., a gold-plated layer, the first solder portion 16 in the molten state is favorably and wetly spread over the entire soldering region. Then, the first solder portion 16 and the second solder portion 17 are solidified by cooling. An insulation bonding member (a bonding member, a resin material, a bonding portion, a fixing portion and the like) such as an underfill-material or a non-conductive film (NCF) is provided between the board 5 and the semiconductor package 4. Consequently, the semiconductor package 4 is fixed to the board 5. In this embodiment, the bonding member 5e is configured by a material whose heat transfer efficiency is lower than solder.

### Second Embodiment

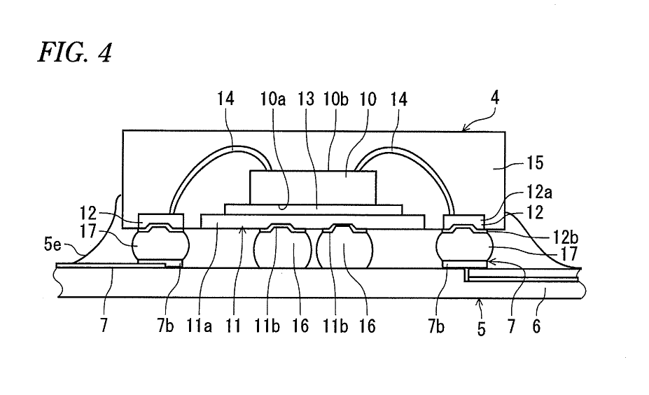

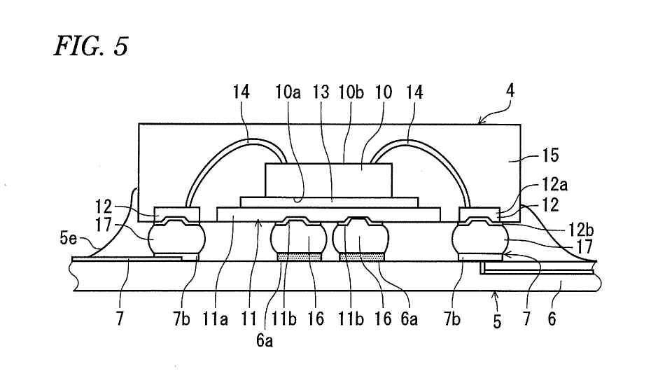

Next, a second embodiment is described with reference to FIGS. 4 and 5. FIG. 4 shows a first modification of the second embodiment. FIG. 5 shows a second modification of the second embodiment. Basically, the present embodiment is similar to the first embodiment. However, the shape of the first solder portion 16 of the semiconductor package 4 differs from that of the first solder portion 16 according to the first embodiment.

As shown in FIGS. 4 and 5, the first electrode portion 11 according to the second embodiment is such that an end of each solder portion 16 abuts against the face of the board 5, which is covered with resist, or a resist protrusion portion 6a at which resist is partly protruded. Thus, according to the present embodiment, the first electrode portion 11 is connected to the board 5/the wiring pattern 7 via the face which is covered with resist or the resist protrusion portion 6a from the first solder portion 16. Accordingly, the first electrode portion 11 is not electrically connected to the board 5 and/or the wiring pattern 7. On the other hand, the second electrode portion 12 is connected to the wiring pattern 7 of the board 5 via the electrode pad 7b from the second solder portion 17. Thus, the second electrode portion 12 is electrically connected to the wiring pattern 7 of the board 5. That is, the signal exchange between the semiconductor package 4 and the board 5 is performed only through a path extending from the second electrode portion 12 to the electrode pad 7b through the second solder portion 17. Although the semiconductor package 4 and the board 5 are physically connected to each other via a path extending from the first electrode portion 11 to the board 5 via the first solder portion 16 and/or the resist protrusion portion 6a, no signal exchange is performed therebetween through this path.

As described above, even in the present embodiment, the first solder portion 16 contributes to the enhanced heat dissipation efficiency in a state in which the first solder portion 16 is not electrically connected to the board 5 and/or the wiring pattern 7. In addition, it is unnecessary to a plating region or the like on the board 5 in order to connect the first solder portion 16 to the board 5. Thus, another electronic component or wiring pattern can be designed to be provided in a region between the first solder portion 16 and the board 5. Consequently, the degree of design can be enhanced.

### Third Embodiment

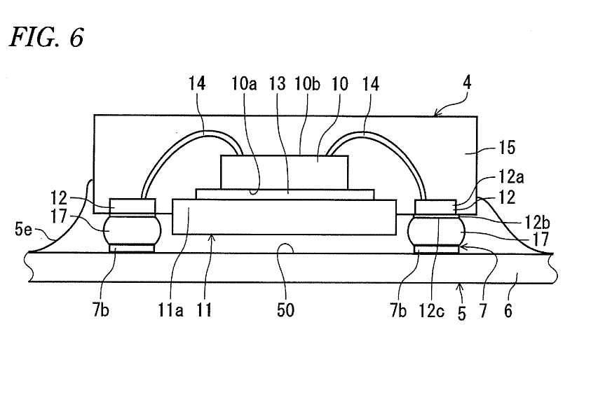

Next, a third embodiment is described hereinafter with reference to FIGS. 6 to 9. Basically, the present embodiment is similar to the first embodiment. However, the third embodiment differs from the first embodiment in the configuration of the first electrode portion 11 of the semiconductor package 4 and the first solder portion 16. As shown in FIGS. 6 to 9, no portion equivalent to the first solder portion 16 exists in the third embodiment.

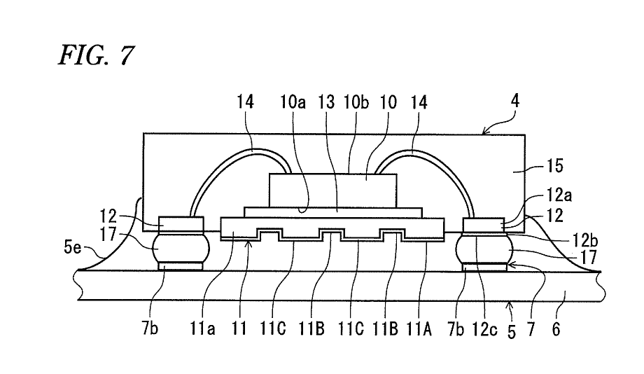

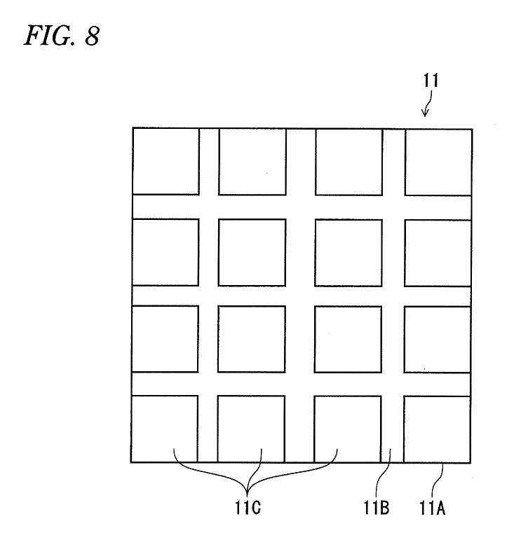

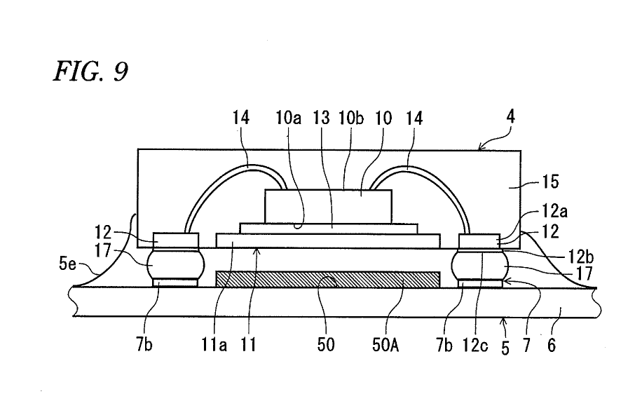

FIG. 6 shows a first modification of the third embodiment. FIG. 7 shows a second modification of the present embodiment. FIG. 8 is a view showing the configuration of the second modification, which is taken from an angle differing from that at which the view shown in FIG. 7 is taken. FIG. 9 shows a third modification of the present embodiment.

First, the first modification of the present embodiment is described hereinafter with reference to FIG. 6.

As shown in FIG. 6, the first modification has a shape in which the first electrode portion 11 protrudes toward the board 5. The first electrode portion 11 is provided to be separated from a surface of the substrate 5. As described above, the first electrode portion 11 is configured by, e.g., an electrically conductive material. That is, the first electrode portion 11 is higher than the bonding member 5e in ability to dissipate heat from the semiconductor package 4, thereby a heat transfer path from the semiconductor package 4 to the board 5 can efficiently be configured. In addition, although the first electrode portion 11 is configured by an electrically conductive material, the first electrode portion 11 is separated from the board 5. That is, similarly to the first solder portion 16 according to the second embodiment, the first electrode portion 11 is physically and electrically separated from the board 5 and/or the wiring pattern 7. With such a configuration, this modification can obtain advantages similar to those of the first embodiment and the second embodiment. Thus, the enhancement of the heat dissipation can be implemented.

Next, the second modification of the third embodiment is described hereinafter with reference to FIGS. 7 and 8.

As shown in FIGS. 7 and 8, similarly to the first modification, according to the second modification, the first electrode portion 11 has such a shape as to protrude towards the board 5. According to the second modification, concave portions 11B and convex portions 11C are provided on a face portion 11A of the first electrode portion 11, which is directed to the board 5. The concave portions 11B and the convex portions 11C are arranged like a grid, so that the area of the face portion 11A of the first electrode portion 11, which is directed to the board 5, is large. The face portion 11A is configured by, e.g., a plating layer. The concave portions 11B and the convex portions 11C can be formed by, e.g., etching, pressing, cutting, and the like. With such a configuration, the present modification can obtain advantages similar to those of the first modification. In addition, the second modification can increase the area of a heat dissipation face. Thus, more enhancement of the heat dissipation efficiency can be implemented.

An example of arranging the concave portions 11B and the convex portions 11C provided on the face of the first electrode portion 11 like a grid has been described hereinabove. However, as long as the heat dissipation efficiency can be enhanced, any configuration of the face thereof can be employed. For example, a configuration of simply graining the face of the electrode portion 11, and that of irregularly providing protrusion portions and depressions on the face thereof can be employed. The depth of each of such concave portions can appropriately be adjusted according to an amount of generated heat, dimensions of components, and the like.

Next, the third modification of the present embodiment is described hereinafter with reference to FIG. 9.

As shown in FIG. 9, the third modification has a protrusion portion (a protrusion portion, a heat transfer portion and the like) 50A, which protrudes towards the semiconductor package 4 and is provided in a region of the board 5 facing the first electrode portion 11. Being similar to the first electrode portion 11, the protrusion portion 50A is configured by an electrically conductive material, e.g., a metallic sealing material, or a plating material. That is, the protrusion portion 50A is higher than the bonding member 5e in ability to dissipate the heat from the semiconductor package 4 and can efficiently configure a heat transfer path extending from the semiconductor package 4 to the board 5. Although the protrusion portion 50A is configured by an eclectically conductive material, the protrusion portion 50A is separated from the semiconductor package 4. That is, similarly to the above second embodiment, the third modification is configured such that the semiconductor package 4 is physically and electrically separated from the board 5 and/or the wiring patterns 7. With such a configuration, the present modification can obtain advantages similar to those of the first embodiment and the second embodiment. Thus, the enhancement of the heat dissipation efficiency can be implemented.

### Fourth Embodiment

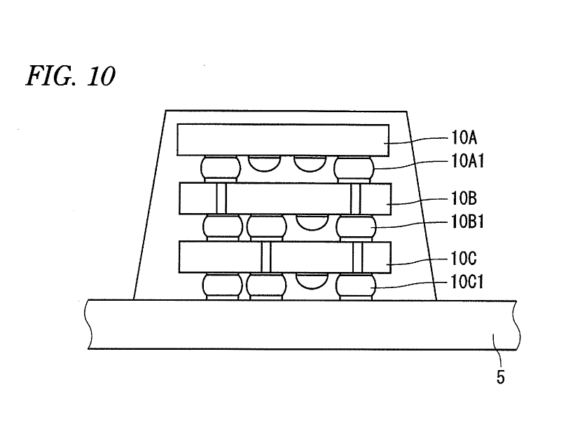

Next, a fourth embodiment is described hereinafter in detail with referring to FIG. 10. Thus the present embodiment differs from the first embodiment in structure of the semiconductor package 4.

As shown in FIG. 10, according to the present embodiment, a plurality of chips 10A, 10B and 10C are provided to overlap with each other in the semiconductor package 4. Each of the semiconductor chips 10A, 10B, and 10C is provided with plural associated solder portions 10A1, 10B1 or 10C1. At least one of the plural solder portions 10A1 is electrically connected to the semiconductor chip 10B overlapping therewith under the chip 10A. At least different one of the plural solder portions 10A1 other than the solder portion 10A1 overlapping with the semiconductor chip 10B provided thereunder is not electrically and physically connected with the associated semiconductor chip 10B provided under the different one of the plural solder portions 10A1. At least one of the plural solder portions 10B1 is electrically connected to the semiconductor chip 10C overlapping therewith thereunder. At least different one of the plural solder portions 10B1 other than the solder portion 10B1 overlapping with the semiconductor chip 10C provided thereunder is not electrically and physically connected with the associated semiconductor chip 10C provided under the different one of the plural solder portions 10B1. At least one of the plural solder portions 10C1 is electrically connected to the board 5. At least one of the plural solder portions 10C1 other than the solder portion 10C1 electrically connected to the board 5 is not electrically and physically connected to the board 5.

That is, each of the semiconductor chips 10A, 10B, and 10C is provided with plural protrusion portions such as the solder portions. At least one of the plural protrusion portions functions as a signal path, and at least one of the plural protrusion portions other than the protrusion portion functioning as the signal path functions as a heat dissipation path but doesn't function as a signal path. With such a configuration, according to the fourth embodiment, a path for transferring heat generated by each of the semiconductor chips 10A, 10B, and 10C to the board 5 can be formed. Thus, the enhancement of the heat dissipation efficiency can be implemented. The connection of the semiconductor chips 10A, 10B, and 10C can preferably be implemented using a combination of the above embodiments and the modifications thereof.

### Fifth Embodiment

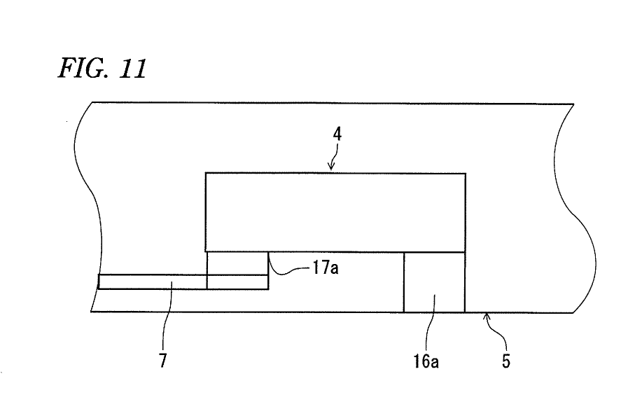

Next, a fifth embodiment is described hereinafter with reference to FIG. 11. The present embodiment differs from the first embodiment in the structure of the semiconductor package 4.

As shown in FIG. 11, the fifth embodiment has a configuration in which the semiconductor package 4 is not a component which is mounted on the board 5, but is incorporated in another electronic component such as the board 5.

The present embodiment is provided with an electrode 17a serving as a protrusion portion for transmitting a signal sent from the semiconductor package 4 to the board 5, and with a protrusion portion 16a which doesn't function as a signal path and which is used to transfer heat from the semiconductor package 4 to the board 5 or to the outside of the board 5. With such a configuration, according to the present embodiment, heat can preferably be let out from heating-elements such as the semiconductor package 4 which is embedded in the board 5 and in which heat is likely to remain. Thus, high heat dissipation efficiency can be implemented.

### Sixth Embodiment

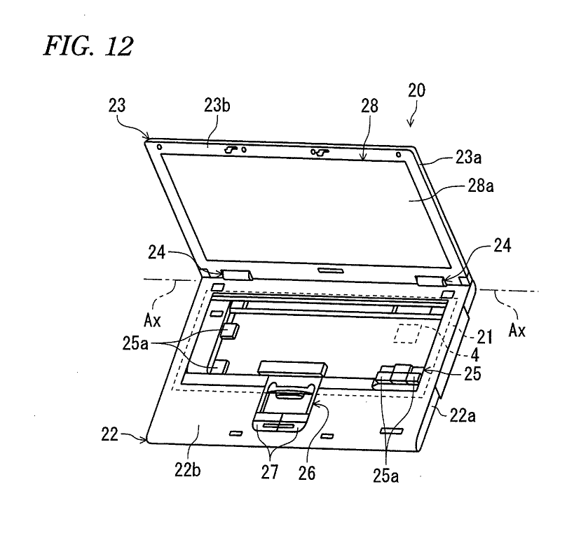

Next, a sixth embodiment is described hereinafter with reference to FIG. 12.

As shown in FIG. 12, an electronic apparatus according to the present embodiment is configured to be what is called a note type personal computer 20. The personal computer 20 includes a first rectangular flat main unit 22 and a second rectangular flat main unit 23. The first main unit 22 and the second main unit 23 are connected via a hinge mechanism 24 to be rotatable around a rotation shaft Aₓ between an unfolded state shown in FIG. 5 and a folded state (not shown).

The first main unit 22 is provided with a keyboard 25 serving as an input operation portion, a pointing device 26, a click button 27 and the like in a state in which such components are exposed towards a front face 22b serving as an outer face of a housing 22a. On the other hand, the second main unit 23 is provided with a display panel 28 serving as a display device (or component) in a state in which the display panel 28 is exposed towards a front face 23b serving as an outer face of a housing 23a. The display panel 28 is configured as, e.g., a liquid crystal display (LCD). In the unfolded state of the personal computer 20, the keyboard 25, the pointing device 26, the click button 27, a display screen 28a of the display panel 28 are exposed so as to be available by a user. On the other hand, in the folded state, the front faces 22b and 23b are placed close and opposed to each other, so that the keyboard 25, the pointing device 26, the click button 27, the display panel 28, and the like are concealed by the housings 22a and 23a. FIG. 12 shows only a part of keys 25a of the keyboard 25.

A board 21 similar to the board 5 described in the first embodiment is housed in the housing 22a of the first main unit 22 or the housing 23a of the first main unit 23 (only in the housing 22a in the present embodiment).

The display panel 28 receives display signals from a control circuit configured by the semiconductor package 4 and the like mounted on the board 21, and displays images such as a still image and a motion picture. A control circuit of a personal computer includes a controller, a storage module (e.g., a read-only memory (ROM), a random access memory (RAM), a hard disk drive (HDD) and the like), an interface circuit, various controllers (not shown). The personal computer 20 incorporates speakers (not shown) or the like for audio output.

The board 21 has a configuration similar to that of the board 5 according to the first embodiment. The semiconductor package 4 is one of those according to the first embodiment through the fifth embodiments. The personal computer 20 serving as the electronic apparatus according to the present embodiment includes the board 21 and the semiconductor package 4 serving as an electronic component structure mounted on the board 21. Accordingly, the sixth embodiment can obtain advantages similar to those obtained by the first to fifth embodiments.

### Seventh Embodiment

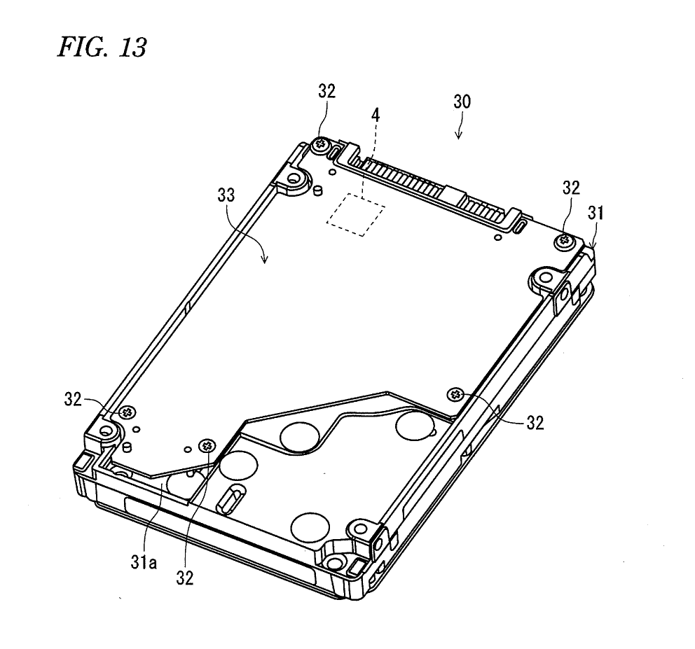

Next, a seventh embodiment is described hereinafter with reference to FIG. 13.

As shown in FIG. 13, an electronic apparatus according to the present embodiment is configured as a magnetic disk apparatus 30. The magnetic disk apparatus 30 includes a flat housing 31 formed like a rectangular flat parallelepiped, which accommodates components such as a magnetic disk (not shown), and a board (printed circuit board) 33 attached to the housing 31 with fastening elements such as screws 32.

The board 33 is placed on a top wall portion 31a of the housing 31. A film-like insulating sheet (not shown) is interposed between the board 33 and the top wall portion 31a. Then, according to the present embodiment, a back face of the board 33, as viewed along a line-of-sight direction in FIG. 13, i.e., a back face (not shown) of the board 33, which faces the top wall portion 31a, is a main mounting face on which a plurality of electronic components including the semiconductor package 4 are mounted. Wiring patterns (not shown) are provided on each of the front face and the back face of the board 33. Apparently, electronic components can be mounted on the front face of the board 33.

Even in the present embodiment, the board 33 has a configuration similar to the board 5 according to the first embodiment. In addition, the semiconductor package 4 mounted on the board 33 is one of the semiconductor packages 4 according to the first to fifth embodiments. That is, the magnetic disk apparatus 30 serving as an electronic apparatus according to the seventh embodiment includes the board 33 and the semiconductor package 4 serving as an electronic component structure mounted on the board 33. Accordingly, even the magnetic disk apparatus according to the present embodiment can obtain advantages similar to those obtained by the first to fifth embodiments.

Thus, as described above, according to each of the above embodiments, an electronic component structure and an electronic apparatus can be provided, in each of which an electrode portion is favorably soldered to a board. In the present application, a television apparatus, a personal computer and a hard disk drive have been described as examples of the electronic apparatus.

While certain exemplary embodiment has been described, the exemplary embodiment has been presented by way of example only, and is not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A television apparatus comprising:
a housing;
a circuit board housed in the housing; and
an electronic component including a first face placed to a side of the circuit board and a second face placed opposite to the first face, and incorporating a silicon member, wherein
the electronic component comprises:
an electrode provided at the first face and configured to be electrically connected to the circuit board; and
a protrusion provided at the first face, placed between the silicon member and the circuit board, and separated from a surface of the circuit board.

2. The apparatus of claim 1, wherein
the electronic component and the circuit board are connected to each other with a resin material, and
the protrusion is placed in the resin material.

3. The apparatus of claim 2, wherein
the protrusion is configured by a material which is higher than the resin material in heat transfer rate, and
the protrusion is configured to be not electrically connected to a surface of the circuit board opposed to the protrusion.

4. The apparatus of claim 3, wherein
at least a part of each of the protrusion and the electrode includes solder paste.

5. The apparatus of claim 3, wherein
the protrusion is a plating layer opposed to a surface of the silicon member.

6. The apparatus of claim 3, wherein
another protrusion protruded to and configured to be electrically connected to the electrode is provided in a region of the circuit board, which faces the electrode.

7. The apparatus of claim 2,
the electric component further comprises:
a lead frame connected to the silicon member;
a plating layer stacked on the lead frame; and
a solder layer provided on the plating layer.

8. The apparatus of claim 2, wherein
the silicon member is incorporated in the electronic component and placed at a side close to the circuit board.

9. An electronic apparatus comprising:
a housing;
a circuit board housed in the housing;
a heating element including a first face placed at a side of the circuit board, and a second face placed opposite to the first face;
an electrode configured to be electrically connected to the first face and the circuit board; and
a protrusion protruded from the first face and separated from the circuit board.

10. An electronic apparatus comprising:
a housing;
a circuit board housed in the housing; and
an electronic component including: a first protrusion protruded towards the circuit board and configured to be electrically connected to the circuit board; and a second protrusion protruded towards the circuit board and configured to be not electrically connected to the circuit board.
